(19) United States
(12) Patent Application Publication
(10) Pub. No.: US 2012/0138977 A1
(43) Pub. Date: Jun. 7, 2012

(54) ANNUAL PACKAGING STRUCTURE FOR LED LAMPS

(76) Inventor: Chia-Mao Li, Taipei (TW)

(21) Appl. No.: 12/960,537

(22) Filed: Dec. 5, 2010

(51) Int. Cl. H01L 33/64

(52) U.S. Cl. 257/89; 257/E33.075

(57) ABSTRACT

An annual packaging structure includes a heat sink having an installation surface; and a plurality of annular isolation walls being formed on the installation surface. Each of two opposite sides of each annular isolation wall has a light reflecting surface. Each installation hole is installed with an insulator material of which is selected from glass or other heat insulation material. Each section is installed with a plurality of LED dies; each LED die being electrically connected to a pin. A heat conduction base has an embedding groove for installing the heat sink. A lower bottom of the embedding groove is formed with a plurality of through holes positioned with respect to the installation holes. The pins are extended through the through holes and are limited by the insulators so that the pin are at a center portion for preventing short-circuit.

### FIELD OF THE INVENTION

The prevent invention related to LED lamps, in particular to a circular shaped heat sink for LED lamps which generate a high power LED light source so as to conduct heat from LEDs to various lamps, such as stage lights, projection lights or other large scale focus lights. The present invention has preferred heat conduction and heat dispersion effect so as to have preferred light efficiency.

### BACKGROUND OF THE INVENTION

In the conventional LED packaging structure, a plurality of LED dies are installed in a substrate, and then the packaging structure is combined with a lampshade, a power supply and related components so as to form as a lamp. However, the prior art lamps have two defects, one is bad heat dissipation which causes the LED lamp to overheat and thus to be destroyed. The other is that the LED dies 16 are widely distributed and the optical control is not good.

Thus, many improved structures are developed for resolving the problem of heat dissipation in the LED packaging structure, but they are used in wide angle illumination; and optical control thereof is difficult so that the use of these packaging structures are limited.

### SUMMARY OF THE INVENTION

To improve the defects in the prior art, the present invention provides an annual packaging structure, comprises: a heat sink having an installation surface; a plurality of annular isolation walls being formed on the installation surface; each of two opposite sides of each annular isolation wall having a light reflecting surface; each recess being formed by at least one section; a plurality of sections being formed as a round area; each section being formed with an installation hole; each installation hole being installed with an insulator material of which is selected from glass or other heat insulation material; each section being installed with a plurality of LED dies; each LED die being electrically connected to a pin; a center of the installation surface having a buffer portion which is a round protrusion; the heat sink being a metal body; a heat conduction base having an embedding groove for installing the heat sink; a lower bottom of the embedding groove being a plurality of through holes positioned with respect to the installation holes; the pins being extended through the through holes and being limited by the insulators so that the pin is at a center portion for preventing short-circuit; the wire connected to the pin being extended out of the lower side; the heat conduction base being a round metal body with preferred heat conduction effect and dispersion effect; each pin passing through a respective through hole to be electrically connected to a circuit; a plurality of light protection layers being installed in the recess for covering the LED die; the section being installed with an LED die; each section having same number of LED dies so that the voltage is controllable the number of LED dies in the section being changeable so as to change the voltage used; LED dies of various colors can be installed so as to present various colors; the annular isolation wall having the effect of preventing heat from one LED die to affect other LED die so as to prolong the lifetime of the LED die; and the buffer portion can prevent the heat concentration due to too many LED dies and having the effect of heat dispersion.

The various objects and advantages of the present invention will be more readily understood from the following detailed description when read in conjunction with the appended drawing.

### BRIEF DESCRIPTION OF THE DRAWINGS

FIG. 1 is an exploded perspective view of the annual packaging structure of the present invention.

FIG. 2 is a perspective view of the annual packaging structure of the present invention.

FIG. 3 is a partial exploded view showing the installation of LED dies and protection layers according to the present invention.

FIG. 4 is a schematic cross section view of the LED dies and the protection layers of the present invention.

FIG. 5 is a schematic view showing light reflection of the annual packaging structure of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

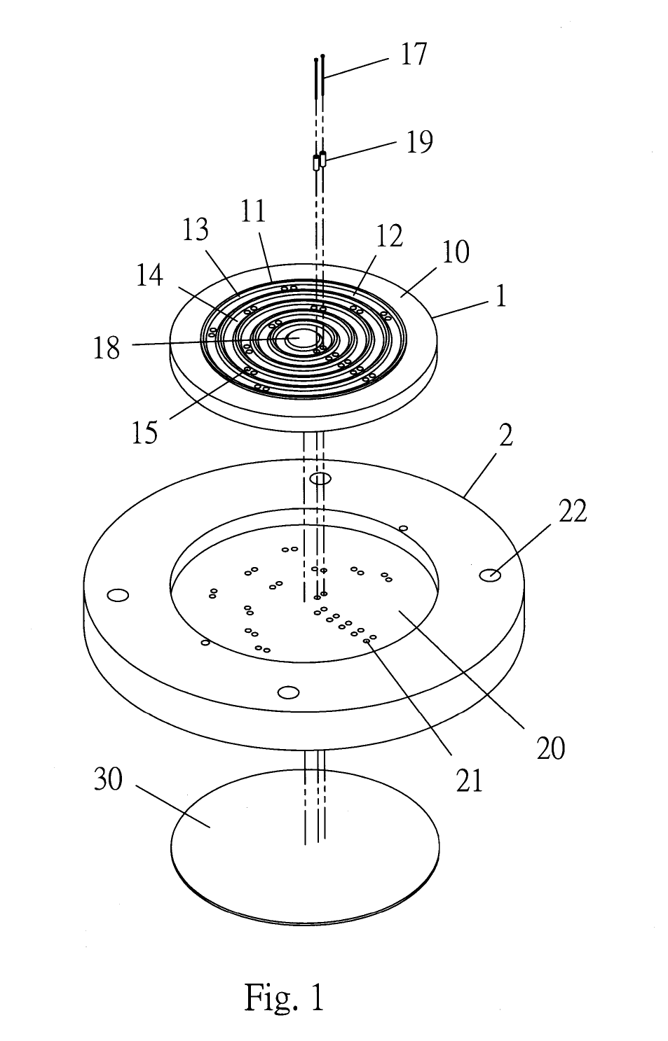

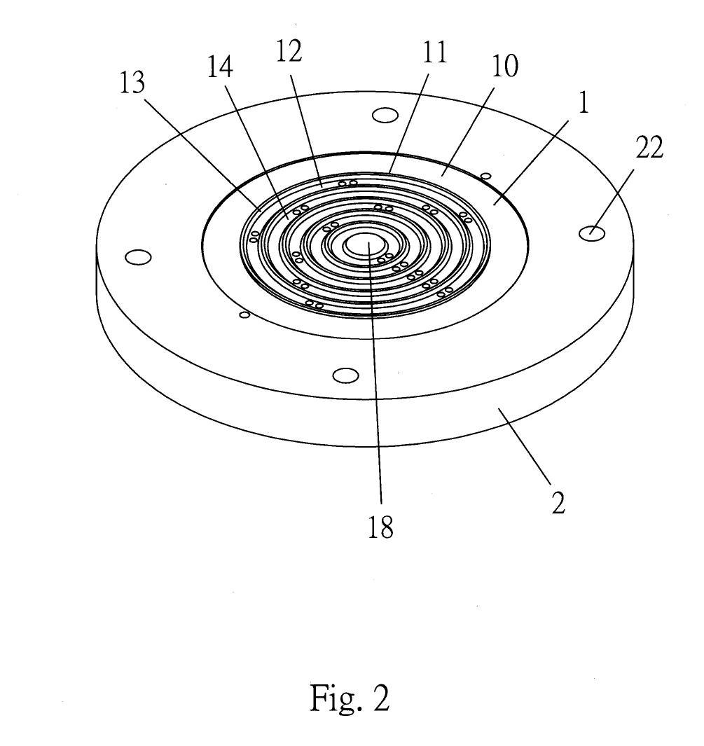

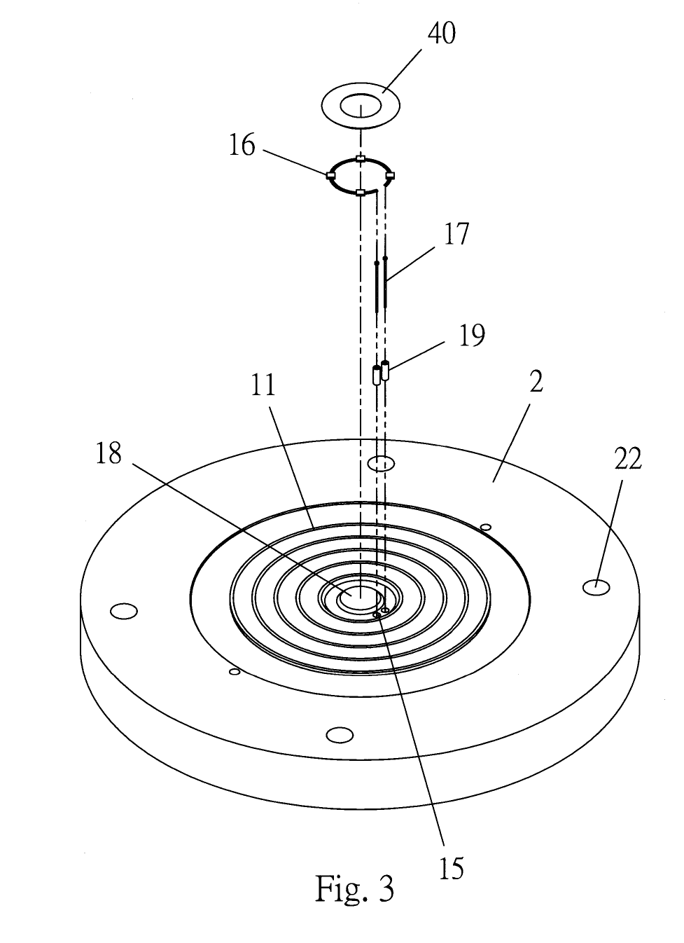

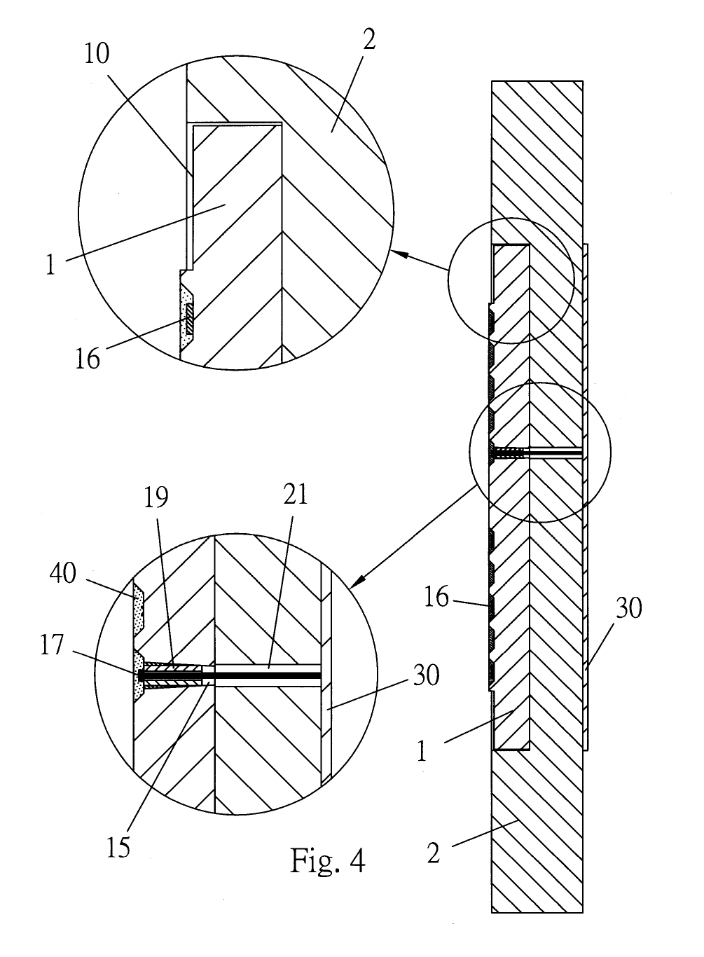

With reference to FIGS. 1 to 4, the circular packaging structure of the present invention is illustrated. The present invention includes the following elements.

A heat sink 11 has an installation surface 10. A plurality of annular isolation walls 11 are formed on the installation surface 10. The area between every two adjacent annular isolation walls 11 is formed as a recess 12. Each recess 12 includes at least one section 14. A plurality of sections 14 are formed as a round area. Each section 14 is formed with an installation hole 15. Each installation hole 15 is installed with an insulator 19 material of which is selected from glass or other heat insulation material. Each section 14 is installed with a plurality of LED dies 16. Each LED die 16 is electrically connected to a pin 17. A center of the installation surface 10 has a buffer portion 18 which is a round protrusion. The heat sink 1 is a metal body with preferred heat conduction and dispersion effect.

A heat conduction base 2 has an embedding groove 20 for installing the heat sink 1. A lower bottom of the embedding groove 20 has a plurality of through holes 21 positioned with respect to the installation holes 15. The pins 17 are extended through the through holes 21 and are limited by the insulators 19 so that the pins 17 are at a center portion for short-circuit-proof. The wire connected to the pin 17 is extended out from the lower side. The heat conduction base 2 is a round metal body with preferred heat conduction effect and dispersion effect. The heat conduction base 2 has a plurality of detaching holes 22 for assembling to a lamp; and by the detaching holes 22, the heat conduction base 2 can be detached quickly.

As illustrated in the drawings, each pin 17 passes through a respective through hole 21 to be electrically connected to a circuit 30. A plurality of light protection layers 40 are installed in the recess 12 for covering the LED die 16.

In the present invention, the section 14 is installed with an LED die 16. Each section 14 has same number of LED dies 16 so that the voltage is controllable.

The number of LED dies 16 in the section 14 is changeable for change of voltage used. LED dies 16 of various colors can be installed for presenting various colors. The annular structure of the sections 14 causes that the light is focusable.

The annular isolation wall 11 has the effect of preventing heat from one LED die 16 to affect other LED die 16 so as to prolong the lifetime of the LED die 16.

Furthermore, the buffer portion 18 can prevent the heat concentration due to too many LED dies 16 and has the effect of heat dispersion.

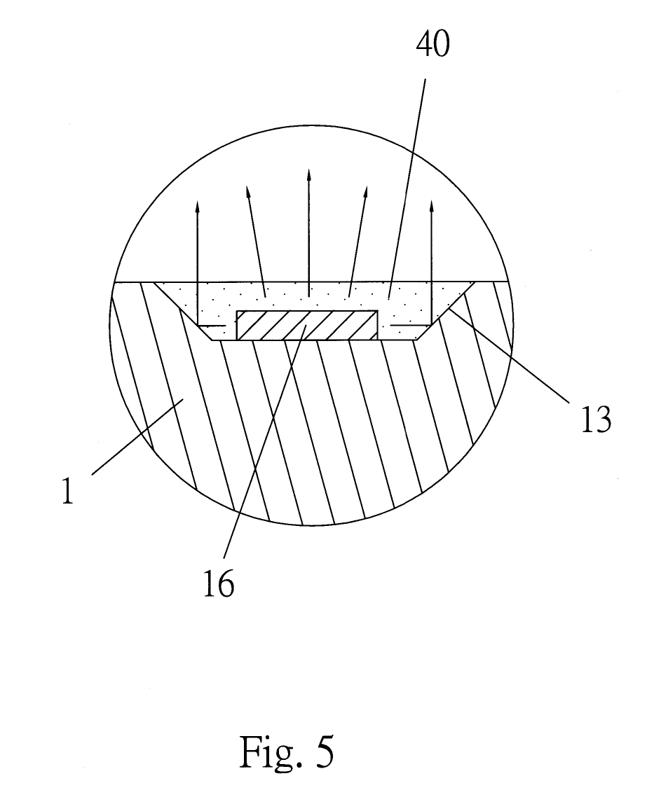

Moreover, a light guide protection layer 40 around the through hole 21 is made of silicide and fluorescence powders. When the LED die 16 lights up, the reflection of the protection layer 40 and the light reflection surface 13 will have the effect of complete reflection, as illustrated in FIG. 5. A preferred optical effect is achieved for providing preferred illumination.

Furthermore, the annular isolation walls 11 are beneficial to the installation of the protection layer 40.

The light reflection effect other than provides the effect of illumination, but also it prevents the heat from the LED dies 16 to be concentrated to some portions so as to protect the protection layer 40.

The heat from the LED dies 16 can be transferred to the heat conduction base 2 through the heat sink 1. The heat conduction base 2 will disperse the heat to the air so as to have the effect of heat dispersion and the lifetimes of the LED dies 16 are prolonged.

Furthermore, the wire connected to the pin 17 is extended out from the rear side which is suitable to the convention way and the assembly and detachment work can be performed easily and quickly.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A circular shaped head sink device, comprising:
a heat sink having an installation surface; a plurality of annular isolation walls being formed on the installation surface; every two adjacent annular isolation walls being formed with a recess; each of two opposite sides of each annular isolation wall having a light reflecting surface; each recess including at least one section; a plurality of sections being formed as a round area; each section being formed with an installation hole; each installation hole being installed with an insulator material which is selected from glass or other heat insulation material; each section being installed with a plurality of LED dies; each LED die being electrically connected to a pin; a center of the installation surface having a buffer portion which is a round protrusion; and the heat sink being a metal body;
a heat conduction base having an embedding groove for installing the heat sink; a lower bottom of the embedding groove being a plurality of through holes positioned with respect to the installation holes; the pins being extended through the through holes and being limited by the insulators so that the pin are at a center portion for preventing short-circuit; the wire connected to the pin being extended out from the lower side; the heat conduction base being a round metal body;
each pin passing through a respective through hole to be electrically connected to a circuit; and a plurality of light protection layers are installed in the recess for covering the LED die;
the section being installed with an LED die; each section having same number of LED dies so that the voltage is controllable;
the number of LED dies in the section being changeable so as to change the voltage used; and LED dies of various colors can be installed for presenting various colors;
the annular isolation wall having the effect of preventing heat from one LED die to affect other LED die so as to prolong the lifetime of the LED die; and
the buffer portion for avoiding the heat concentration due to too many LED dies and having the effect of heat dispersion.

2. The circular shaped heat sink device as claimed in claim 1, wherein the heat conduction base has a plurality of detaching holes for assembling with a lamp and by which the heat conduction base can be detached quickly.

3. The circular shaped heat sink device as claimed in claim 1, wherein light guide protection layer is around the through hole.

4. The circular shaped heat sink device as claimed in claim 1, wherein the insulator is selected from glass or other heat insulation material.
